(19) United States
(12) Patent Application Publication
(10) Pub. No.: US 2007/0267621 A1
(43) Pub. Date: Nov. 22, 2007

(54) RESISTIVE MEMORY DEVICE

(75) Inventor: Klaus Dieter Ufert, Unterschleissheim (DE)

Correspondence Address: DICKE, BILLIG & CZAJA, FIFTH STREET TOWERS, 100 SOUTH FIFTH STREET, SUITE 2250, MINNEAPOLIS, MN, 55402, US

(73) Assignee: INFINEON TECHNOLOGIES AG, Munchen (DE)

(21) Appl. No.: 11/436,979

(22) Filed: May 19, 2006

(51) Int. Cl. H01L 47/00

(52) U.S. Cl. 257/4

(57) ABSTRACT

A programmable resistive memory cell comprising a lower electrode, a programmable resistance layer, and an upper electrode, wherein the programmable resistance layer comprises a first transition metal oxide and a second transition metal oxide.

### TECHNICAL FIELD OF THE INVENTION

The invention relates to a programmable resistive memory cell with a programmable resistance layer and to a method of fabricating a resistive memory cell with a programmable resistance layer.

### BACKGROUND OF THE INVENTION

Conventional electronic data memories, for example dynamic random access memory (DRAM) or flash RAM, increasingly run into limits when they are to meet modern requirements. Conventional concepts for electronic data memories, as are also employed in the case of DRAM and flash RAM, store information units in capacitors, wherein a charged or an uncharged state of the capacitor represent, for instance, the two logic states “1” or “0”.

In case of the DRAM, the capacitors are designed extremely small in order to achieve high information density and integration, and thus require constant refreshing of the stored information content. Besides additional memory controllers for refreshing, this also requires substantial energy. On the other hand, the flash RAM retains the stored information content without external power being supplied, but the individual flash RAM memory cells require high voltages for writing information and provide a limited endurance only. Therefore, modern electronic data memories have to be capable of combining high information density, short access time and non-volatility. Here, non-volatility denotes the characteristic of an electronic data memory, that it can reliably store the information content for a considerable time span without the need for an external supply of energy.

The requirements with respect to information density and non-volatility become apparent also in portable applications, since the available space is limited and the batteries, serving as a power supply, are only able to provide limited energy and voltages. In order to combine the non-volatility with a short access time and high integration, alternatives to the DRAM or the flash RAM are subject to intense scientific and industrial research and development. Amongst others, the so-called resistive electronic data memories represent a promising concept.

Besides solid electrolytes, phase transition cells, or other special materials, a high- and low-resistive electrical state may be reliably and stably imposed to transition metal oxide layers. Thus, a low-resistive state may correspondingly represent a logic state “1”, and a high-resistive state may represent a logic state “0”, for example. Such layers further allow a differentiation of several resistive states, such to store reliably a plurality of distinguishable logic states in one cell, which is also referred to as multi-bit capability.

The process of storing information in a transition metal oxide (TMO) layer is based on the principle that a low-resistive filament may be formed in a TMO by means of local heating. Said local heating is generated by a current through the initially high-resistive TMO. Once formed, the filament shorts the otherwise high-resistive TMO and thereby substantially changes the effective electrical resistance. By means of applying a sufficiently low voltage, the resistive and hence the logic state of the memory cell with a TMO layer may be determined via measuring the resulting current. An existing filament may be interrupted again by a sufficiently high current, and thus the TMO storage cell returns to a high-resistive state. This process is reversible and has been demonstrated also for a technically relevant repetition rate in the range of 10⁶. Therein, a TMO storage cell is usually formed by a lower electrode, an upper electrode and a TMO layer arranged in between. The minimum size of such a TMO memory cell is primarily given by lithographic limitations with respect to the patterning of the electrodes.

Typically, an individual filament, substantially lowering the electric resistance of a TMO storage cell, is often much smaller in cross-section than the contact area of the electrodes, the ladder being manufactured by modern lithographic and patterning techniques. During the programming of a TMO memory cell, several filaments start to form initially, until a first continuous filament shorts the lower and upper electrodes. At this point, also the further formation of the remaining filaments stops, due to most of the current then being conducted through the continuous filament. Once a first continuous filament is formed, this filament may be interrupted again by a corresponding erase current. This rupture of the filament, again, returns the TMO memory cell to a high-resistive state.

Thus, reprogramming the TMO memory cell to a low-resistive state again may then be narrowed to the change of the resistance in that region of the interrupted filament, and therefore requires substantially less energy and time than the initial transformation from the initial high-resistive state to a low-resistive state. The first formation of filaments requires, usually dependent on the defect concentration, substantially higher programming voltages than the switching of a TMO storage cell during regular operation. However, initial programming with a high voltage is usually necessary.

However, the high initial programming voltages are in conflict with the integration of TMO storage cells. The smaller a TMO memory cell is structured, the lower falls also the breakdown voltage of the TMO layer. The application of a voltage in the range of the breakdown voltage may adversely alter the memory cell or may also result in a complete failure thereof after only a few switching cycles.

Conventional TMO storage cells therefore employ an only partial oxidation of the TMO layer, in order to lower the initial resistance and thus also for lowering the required initial programming voltage. Therein, the used transition metal oxide is formed with less oxygen than stoichiometrically possible. In this way, both the initial electrical resistance and the temperature-dependence of the resistance are lowered and flattened, respectively. Flattening of the temperature-dependence of the resistance allows for an programming of the TMO memory cell by means of a substantially lowered voltage and, in general, the required voltage for heating the layer may be reduced. A characterization of the temperature-dependence of a resistance ρ(T) may be achieved by means of the so-called activation energy E according to

ρ(T)=ρ₀ exp{−E/(kT)}, (1)

wherein k is Boltzmann's constant, approximately equaling 1.38×10⁻²³ J/K, and wherein, according to (1), the resistance ρ(T) decreases for higher temperatures T.

However, problems arise as far as the manufacturing and the operation of oxygen-deficient transition metal oxides are concerned: The controlled and well-defined deposition of oxygen-deficient transition metal oxides is difficult to achieve with a satisfactory degree of reproducibility. Furthermore, oxygen may diffuse into or out of the ready structured TMO memory cell, and the electrical characteristics of the TMO memory cell then may change a posteriori, this alteration of the electrical characteristics especially taking place during subsequent manufacturing steps, e. g. being part of a back end of line (BEOL), and also during regular operation.

### SUMMARY OF THE INVENTION

The present invention provides advantages for an improved programmable resistive memory cell, and an improved method of fabricating a programmable resistive memory cell.

In one embodiment of the present invention, a programmable resistive memory cell is provided, the memory cell including a lower electrode, a programmable resistance layer, and an upper electrode, wherein the programmable resistance layer comprises a first transition metal oxide and a second transition metal oxide, and wherein a single transition metal forms the first transition metal oxide and the second transition metal oxide.

In another embodiment of the present invention, a programmable resistive memory cell is provided, the memory cell includes a lower electrode, a programmable resistance layer, and an upper electrode, wherein the programmable resistance layer comprises a first transition metal oxide and a second transition metal oxide, and wherein a first transition metal forms the first transition metal oxide and a second transition metal forms the second transition metal oxide.

In still another embodiment of the present invention, a method of fabricating a resistive memory cell is provided, the method includes providing a lower electrode, providing a programmable resistance layer, and providing an upper electrode, wherein the programmable resistance layer comprises a first transition metal oxide and a second transition metal oxide, and wherein a single transition metal is oxidized to form the first transition metal oxide and the second transition metal oxide.

In yet another embodiment of the present invention, a method of fabricating a resistive memory cell is provided, the method includes providing a lower electrode, providing a programmable resistance layer, and providing an upper electrode, wherein the programmable resistance layer comprises a first transition metal oxide and a second transition metal oxide, and wherein a first transition metal is oxidized to form the first transition metal oxide and a second transition metal is oxidized to form the second transition metal oxide.

### BRIEF DESCRIPTION OF THE DRAWINGS

The above recited features of the present invention will become clear from the following description, taken in conjunction with the accompanying drawings. It is to be noted, however, that the accompanying drawings illustrate only typical embodiments of the present invention and are, therefore, not to be considered limiting of the scope of the invention. The present invention may admit other equally effective embodiments.

FIGS. 1A and 1B show a schematic view of conventional programmable resistive memory cells.

FIGS. 2A and 2B show a schematic plot of the temperature-dependent resistance of conventional TMO memory cells.

FIG. 2C shows a schematic plot of the temperature-dependent resistance of a TMO memory cell, according to a first embodiment of the present invention.

FIGS. 3A through 3C show a schematic view of a programmable resistive memory cell in various stages during fabrication, according to a second embodiment of the present invention.

FIGS. 4A through 4H show a schematic view of a programmable resistive memory cell in various stages during fabrication, according to a third embodiment of the present invention.

FIG. 5A shows a schematic view of a programmable resistive memory cell, according to a fourth embodiment of the present invention.

FIG. 5B shows a schematic view of a programmable resistive memory cell as a part of an integrated circuit according to a fifth embodiment of the present invention.

### DETAILED DESCRIPTION OF THE INVENTION

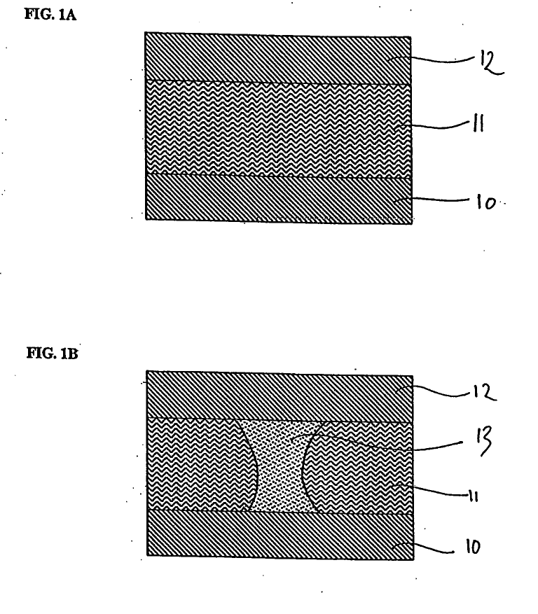

FIG. 1A shows a schematic view of a conventional programmable resistive memory cell with a lower electrode 10, a programmable resistance layer 11, and an upper electrode 12. By applying electrical signals to the lower electrode 10 and the upper electrode 12, a current may flow through the programmable resistance layer 11, which locally heats the programmable resistance layer 11, whereby the electrical resistance can locally change. A finite local current density in the programmable resistance layer 11 results in local heating and thus in formation of a conductive region 13, as shown in FIG. 1B. As soon as a filament 13 has been formed, this filament 13 represents a short between the lower electrode 10 and the upper electrode 12, hence the programmable resistive memory cell will assume a low-resistive state.

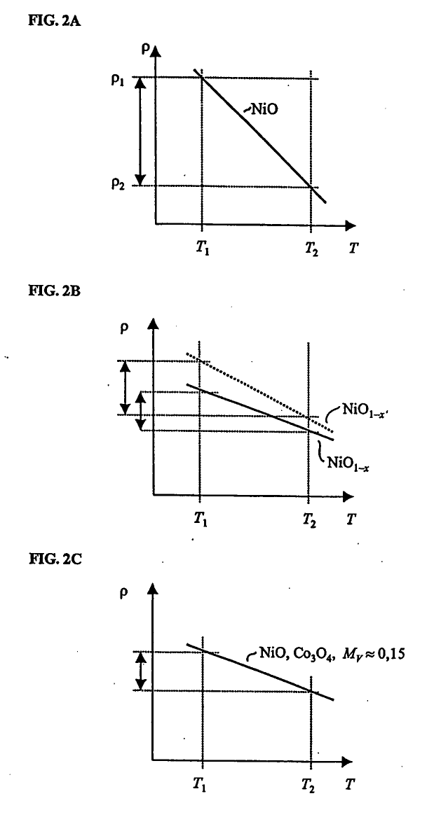

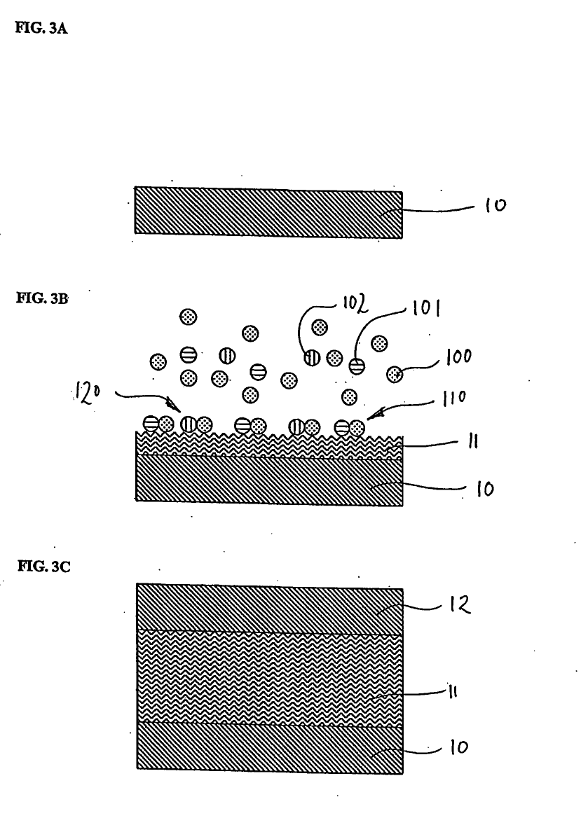

FIG. 2A shows a schematic plot of the temperature-dependent resistance of a conventional nickel oxide layer. Therein, the resistance ρ is plotted versus the temperature T. As shown, for example, for a temperature T ranging from room temperature T₁ to approximately T₂≈300° C. the temperature-dependent resistance substantially drops linearly from approximately 10⁸ . . . 10⁹ Ωcm to 10⁵ . . . 10⁶ Ωcm. Initially, a stoichiometric nickel oxide layer with few defects therefore has an initial electric resistance of approximately 10⁸ . . . 10⁹ Ωcm at room temperature. As a result, a high voltage is required to generate a sufficient current and heating in the programmable resistance layer. In stoichiometric TMO layers with few defects this voltage may be in the range of the breakdown voltage of the programmable resistive layer. Applying such a high voltage for initially generating conductive filaments in the programmable resistance layer may therefore result in an adverse alteration of the programmable memory cell or in a complete failure of the cell after only a few switching cycles, hence strongly and adversely affecting the memory cell's endurance.

FIG. 2B shows a schematic plot of the temperature-dependent resistance of a nickel oxide layer with an oxygen deficiency: As a solid line, the resistance of an NiO₁₋ₓ layer is plotted, and, as a dotted line, the resistance of an NiO_{1-x′} layer is plotted. Therein, x and x′ are often in a range of 0.15 to 0.65, and, in this range, already a substantial change of the temperature-dependent resistance in the order of 3 to 4 orders of magnitude is obtained. In order to achieve a well-defined and desired initial electrical resistance and a well-defined and desired temperature-dependence of the resistance of an NiO₁₋ₓ layer, the respective NiO₁₋ₓ layer has to be deposited with high precision, the required precision being approximately x±3%. Furthermore, this stoichiometric oxygen deficit must also be maintained reliably in the nickel oxide layer during further fabrication stages and/or operation. The reliable and reproducible deposition of such an oxide layer is difficult to achieve and may be maintained, for example, by means of expensive and elaborate diffusion barriers.

FIG. 2C shows a schematic plot of the temperature-dependent resistance of a combination of two transition metal oxides, for example, nickel oxide and cobalt oxide, according to a first embodiment of the present invention. Therein, a programmable resistance layer comprises two transition metal oxides, TMO₁ and TMO₂, in an atomic/molecular ratio

M_{R}=TMO₁/(TMO₁+TMO₂), (2)

wherein TMO₁ and TMO₂ denote the respective atomic content of the first and second transition metal oxide. The ratio M_{R}, as defined by (2), may determine both the initial electrical resistance and the temperature-dependence of the electrical resistance of the combined oxide layer. The ratio M_{R} may be set reliably and reproducibly during deposition, for example, during sputtering, by varying the corresponding sputtering rates. In addition, the ratio M_{R} may then be stably maintained in the programmable resistance layer even without the need for diffusion barriers or other measures. Using corresponding transition metal oxides, both the initial electrical resistance and the temperature-dependence thereof may be atuned in a large range. In the case of a nickel oxide/cobalt oxide combination, the ratio M_{R} may vary in the range of 0.1 to 0.15 or, as an upper limit, to 0.25. A variation of M_{R} in the range of 0 to 0.5 may vary the electric resistance by approximately 6 orders of magnitude.

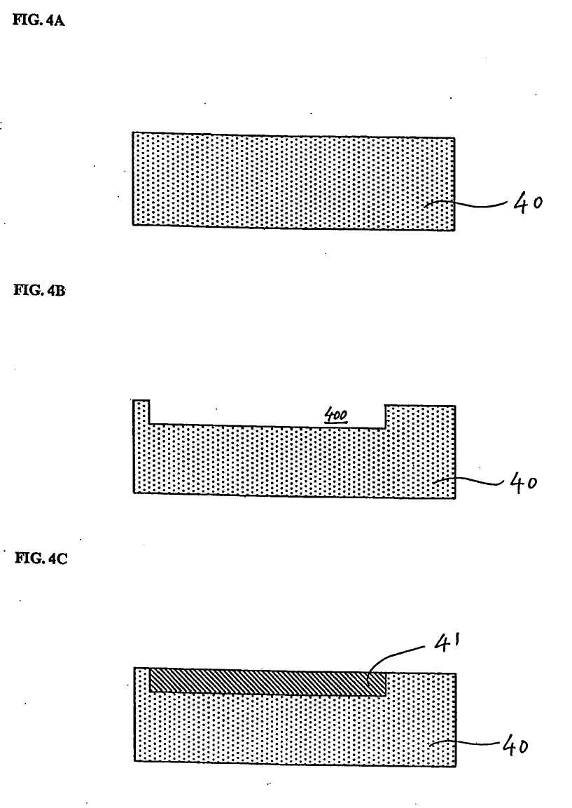

FIGS. 3A through 3C show a schematic view of a resistive memory cell in different stages during fabrication according to a second embodiment of the present invention. As shown in FIG. 3A, first, a lower electrode 10 is provided. As shown in FIG. 3B, a programmable resistive layer 11 is provided on the lower electrode 10, for example, by means of reactive co-sputtering. During sputtering, a DC, MF or RF plasma excitation may be effected, in order to sputter a solid element or oxide target. Therein, at least two transition metals, a first transition metal 101 and a second transition metal 102, are sputtered. In the case of sputtering elementary transition metals, the process atmosphere during formation of the programmable resistance layer 11 comprises oxygen 100 for forming the corresponding oxides 110, 120. As shown, the process atmosphere comprises at least so much oxygen 100 that the sputtered transition metals 101 and 102 may oxidize in their respective highest degree of oxidation and thus form a stable and completely oxidized first transition metal oxide 110 and a stable and completely oxidized second transition metal oxide 120. There may be no need for the provision of further diffusion barriers and liners and other encapsulations, as the fully oxidized transition metal oxides remain stable and are not prone to alter their electrical characteristics due to diffusion from or to the outside of the layer. This may not only simplify fabrication, for instance being embedded into a CMOS manufacturing process, but also allows for a further miniaturization and a higher integration of resistive memory cells.

The relative content of the first and the second transition metal oxides in the programmable resistance layer 11 is in this case depending on the respective sputtering rates of the respective transition metals 101, 102. Possible transition metal oxides are nickel oxide, titanium oxide, niobium oxide, hafnium oxide, zirconium oxide, chromium oxide, tantalum oxide, vanadium oxide, iron oxide, manganese oxide, or cobalt oxide. For example, nickel oxide, hafnium oxide, and zirconium oxide are relatively high-resistive, whereas chromium oxide, cobalt oxide, tantalum oxide, or vanadium oxide are relatively low-resistive. The transition metal oxides have different resistances such that a desired value of the initial resistance and the temperature-dependence of the resistance may be adjusted and tuned by the appropriate combination and/or mixture of a first transition metal oxide with a relatively high resistance and a relatively steep temperature dependence and a second transition metal oxide with a relatively low resistance and a relatively flat temperature dependence. This may result in an intermediate initial resistance and an intermediate temperature dependence of the resistance of the programmable resistance layer 11. Hence the required initial programming voltage may be reduced and may be well below the breakdown voltage. In addition to this, also two different oxides of the same transition metal may be employed to form a programmable resistance layer with a desired resistance. An example for a possible material system is Fe₂O₃ in combination with FeO and/or Fe₃O₄.

As shown in FIG. 3C, an upper electrode 12 is deposited on the programmable resistance layer 11. Electric signals can then be applied on the electrodes 10, 12 for forming conductive filaments in the programmable resistance layer 11 and for determining the resistive state of the programmable resistance layer 11. Suitable materials for the lower electrode 10 and the upper electrode 12 are high-temperature melting materials and may include for example tungsten, platinum, palladium, or titanium.

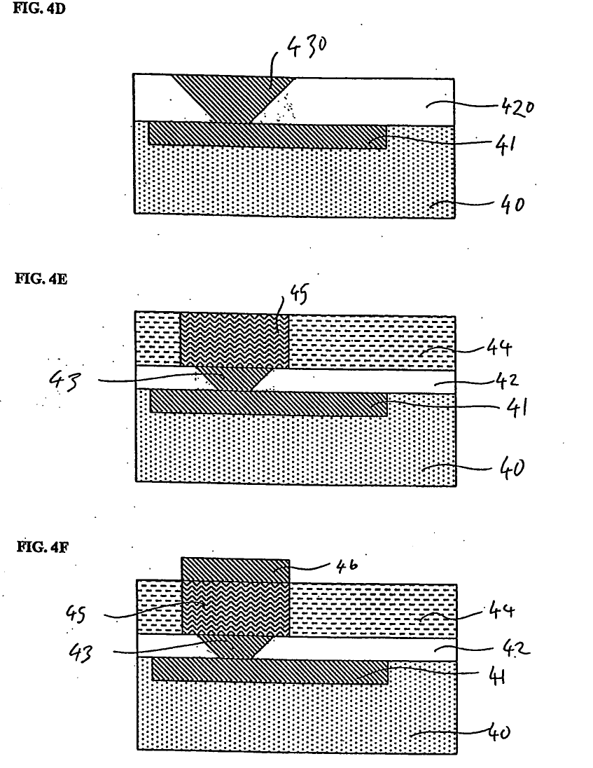

FIGS. 4A through 4H show a schematic view of a resistive memory cell in different stages during fabrication according to a third embodiment of the present invention. First, as shown in FIG. 4A, a substrate 40 is provided. As shown in FIG. 4B, a trench 400 is formed in the substrate 40. The substrate 40 may include a silicon substrate or other already structured functional elements—as is usual in semiconductor manufacturing. The trench 400 in the substrate 40 serves for forming a lower electrode 41, as shown in FIG. 4C. In the case of a insulating or semi-insulating substrate 40, a plurality of lower electrodes 41 or also conductive tracks may be arranged side-by-side for contacting a plurality of resistive memory cells, wherein the contacts or tracks are electrically isolated from each other.

The surface of the lower electrode 41 and of the substrate 40 may be polished, e. g. by means of chemical mechanical polishing, for the provision of a planar surface for the following process stages.

As shown in FIG. 4D, a contact mold layer 420 and a contact 430 are provided on the substrate 40 and the lower electrode 41. Therein, the contact mold layer 420 may be deposited by a CVD method for example from SiO₂ or Si₃N₄. The contact 430 may be furthermore tapered downward. The opening in the contact mold layer 420 may be effected sub-lithographically such that a contact area from the contact 430 to the lower electrode 41 may be formed small, and also smaller with respect to conventional lithographic techniques. Starting from the contact mold layer 420 and the contact 430, as shown in FIG. 4D, the contact mold layer 420 and the contact 430 may be polished and thus be reduced in height. The tapered design of the contact 430 reduces a surface of the contact 43 upon polishing, or, in general upon reduction of the layer height, as shown in FIG. 4E. When the desired surface of the contact 43 or the desired height of the contact 43 and the contact mold layer 42 has been reached, an intermediate isolating layer 44 with a trench is provided on top of the contact 43 and the contact mold layer 42. Said trench is filled with a programmable resistance layer 45. Thereupon, polishing may be again effected.

An upper electrode 46 is formed on the programmable resistance layer 45, as shown in FIG. 4F. For passivation and for protection of the programmable resistive memory cell, as shown in FIG. 4G, a top insulating layer 47 may be applied. According to this embodiment of the present invention, the contact plug, consisting of the lower electrode 41 and the contact 43, reduces the effective contact area between the contact 43 and the programmable resistance layer 45, and thus significantly restricts the region, in which a conductive filament 48 may be formed, as shown in FIG. 4H. Furthermore, individual resistive memory cells can also be arranged tightly side-by-side without an interaction of adjacent memory cells reducing the reliability of the respective memory or logic integrated devices.

With regard to the fabrication and the materials of the electrodes and contacts 41, 43, 46, and the programmable resistance layer 45, respectively, the techniques and materials as described in conjunction with FIGS. 3A through 3C may be employed.

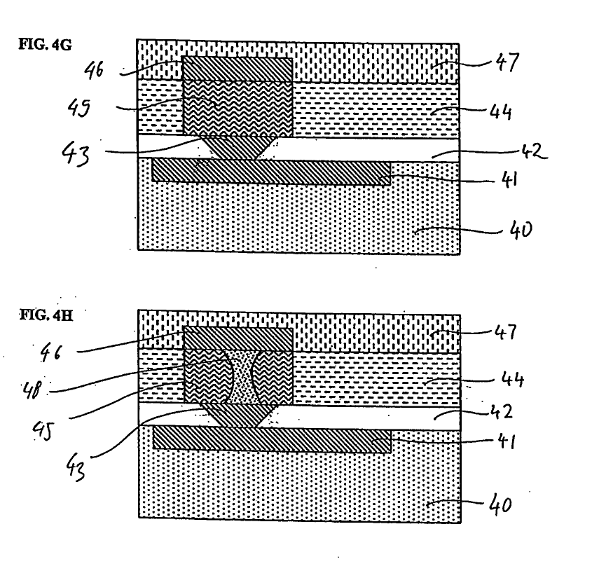

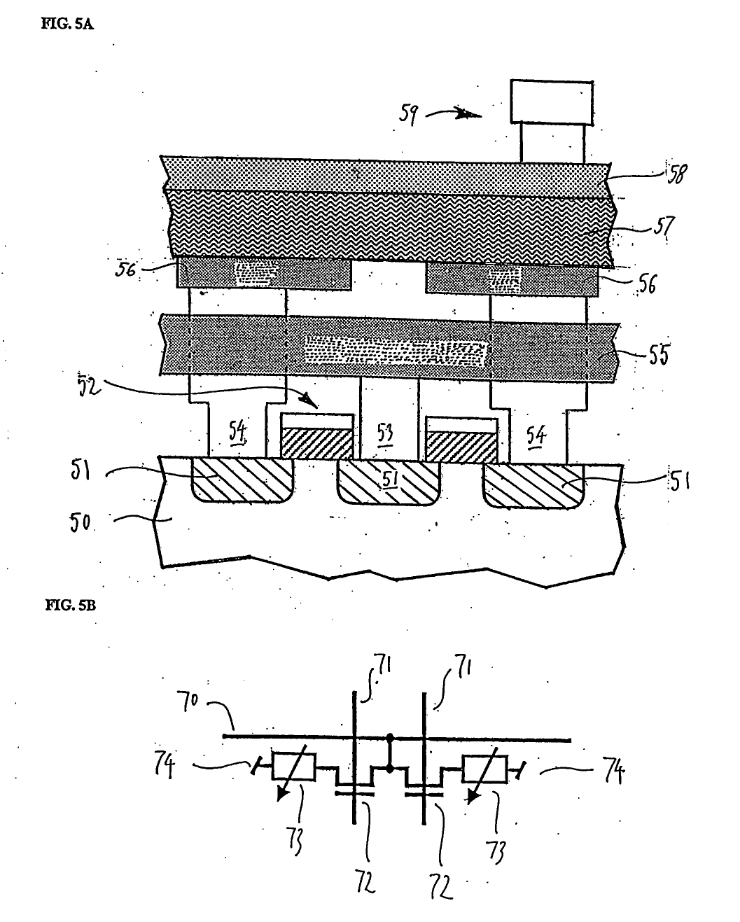

FIGS. 5A and 5B show a schematic view of a programmable resistive memory cell being part of an integrated circuit, according to a fourth and fifth embodiment of the present invention. As shown in FIG. 5A, first, doped regions 51 are provided in a substrate 50. Therein, a doped region 51 is connected through a via 53 to a bit line 55. Word lines 52 include a gate electrode and thus control the conduction between the doped regions 51. The doped regions 51 can also be coupled to bottom electrodes 56 with vias 54. Between the bottom electrodes 56 and a top electrode 58, a programmable resistance layer 57 is arranged, in which filaments may be formed and interrupted by electrical signals. The top electrode 58 is connected to further components of the integrated circuit through a via 59.

By activating the corresponding bit line 55 and the corresponding word line 52, an electrical signal can be applied between the via 59, the top electrode 58, the programmable resistance layer 57, the bottom electrode 56, the via 54, two adjacent doped regions 51—coupled by means of the corresponding word line 52, the via 53, and the bit line 55, for programming or reading-out a resistive state of a region of the programmable resistance layer 58.

In FIG. 5B, two resistive memory cells 73 are shown schematically in a circuit diagram. The resistive memory cells 73 are connected to a common bit line 70 through selection transistors 72. By corresponding activation of the selection transistors 72 with the word lines 71, an electrical signal can be applied between the bit line 70, through an enabled selection transistor 72, a resistive storage cell 73 and the electrode 74. This electrical signal can be effected for generating a current through the corresponding resistive storage cell 73 for programming or for reading-out the cell's resistive state. An integrated storage device then contains a plurality of resistive storage cells 73, each being associated to a selection transistor 72, and a corresponding set of bit lines 70 and a set of word lines 71, the latter two often being arranged perpendicularly to each other.

With regard to the fabrication and the materials of the electrodes and contacts 56, 58, and the programmable resistance layer 57, the techniques and materials as described in conjunction with FIGS. 3A through 3C may be employed.

The preceding description only describes advantageous exemplary embodiments of the invention. The features disclosed therein and the claims and the drawings can, therefore, be essential for the realization of the invention in its various embodiments, both individually and in any combination. While the foregoing is directed to embodiments of the present invention, other and further embodiments of this invention may be devised without departing from the basic scope of the invention, the scope of the present invention being determined by the claims that follow.

What is claimed is:

1. An integrated circuit device, comprising:
a lower electrode;
a programmable resistance layer; and
an upper electrode,
wherein the programmable resistance layer comprises a first transition metal oxide and a second transition metal oxide.

2. The integrated circuit device as claimed in claim 1, wherein one of the transition metal oxides is oxidized in its highest degree of oxidation.

3. The integrated circuit device as claimed in claim 1, wherein one of the transition metals niobium, titanium, nickel, zirconium, chromium, cobalt, manganese, vanadium, tantalum, hafnium, or iron forms at least one of the transition metal oxides.

4. The integrated circuit device as claimed in claim 1, wherein the programmable resistance layer comprises at least one of the metals of strontium, lead, tungsten, praseodymium, or calcium.

5. The integrated circuit device as claimed in claim 1, wherein an initial electrical resistance of the programmable resistance layer is smaller than 10⁹ Ωcm.

6. The integrated circuit device as claimed in claim 1, wherein the activation energy of a temperature-dependent electrical resistance of the programmable resistance layer is smaller than 0.7 eV.

7. The integrated circuit device as claimed in claim 1, wherein the lower electrode and the upper electrode comprise at least one of the metals tungsten, platinum, titanium, or palladium.

8. The integrated circuit device as claimed in claim 1, wherein the programmable resistance layer is surrounded by an insulating layer.

9. The integrated circuit device as claimed in claim 1, wherein a contact is arranged between the lower electrode and the programmable resistance layer, wherein the contact is surrounded by an insulating contact mold layer.

10. The memory cell integrated circuit device as claimed in claim 9, wherein the contact is tapered downwards.

11. The integrated circuit device as claimed in claim 1, wherein a first transition metal forms the first transition metal oxide and a second transition metal forms the second transition metal oxide.

12. The integrated circuit device as claimed in claim 1, wherein a single transition metal forms the first transition metal oxide and the second transition metal oxide.

13. The integrated circuit device as claimed in claim 11, wherein the first transition metal oxide and the second transition metal oxide are oxidized in their highest degree of oxidation.

14. The integrated circuit device as claimed in claim 11, wherein at least one of the transition metals niobium, titanium, nickel, zirconium, chromium, cobalt, manganese, vanadium, tantalum, hafnium, or iron forms a transition metal oxide.

15. The integrated circuit device as claimed in claim 11, wherein the programmable resistance layer comprises nickel oxide and cobalt oxide.

16-22. (canceled)

23. A method of fabricating an integrated circuit device, comprising:
providing a lower electrode;
providing a programmable resistance layer; and
providing an upper electrode,
wherein the programmable resistance layer comprises a first transition metal oxide and a second transition metal oxide.

24. The method as claimed in claim 23, wherein one of the transition metal oxides is oxidized in its highest degree of oxidation.

25. The method as claimed in claim 23, wherein the provision of the programmable resistance layer is effected by means of sputtering.

26. The method as claimed in claim 25, wherein two transition metal oxides are sputtered in a process atmosphere, the process atmosphere comprising an inert gas.

27. The method as claimed in claim 26, wherein the process atmosphere comprises argon.

28. The method as claimed in claim 23, wherein an initial electrical resistance of the programmable resistance layer is tuned by a ratio of the first transition metal oxide to the second transition metal oxide, and the initial electrical resistance of the programmable resistance layer is smaller than 10⁹ Ωcm.

29. The method as claimed in claim 23, wherein the activation energy of a temperature-dependent electrical resistance of the programmable resistance layer is tuned by a ratio of the first transition metal oxide to the second transition metal oxide, and the activation energy of the temperature-dependent electrical resistance of the programmable resistance layer is smaller than 0.7 eV.

30. The method as claimed in claim 23, wherein providing the lower electrode comprises:
etching a trench in a substrate;
filling the trench with a conductive material; and
polishing the conductive material.

31. The method as claimed in claim 30, further comprising:
providing a contact mold layer;
etching a trench in the contact mold layer;
filling the trench in the contact mold layer with conductive material; and
polishing the contact mold layer and the conductive material in the trench such to form a contact on the lower electrode, wherein the contact is surrounded by the contact mold layer.

32. The method as claimed in claim 31, wherein the trench is tapered downward in the contact mold layer.

33. The method as claimed in claim 32, wherein the conductive material in the trench and the contact mold layer are polished such to reduce an upper area of the contact.

34. The method as claimed in claim 33, wherein the polishing is effected by means of chemical mechanical polishing.

35. The method of claim 23, wherein
wherein a first transition metal is oxidized to form-the first transition metal oxide and a second transition metal is oxidized to form the second transition metal oxide.

36. The method as claimed in claim 23, wherein a single transition metal is oxidized to form the first transition metal oxide and the second transition metal oxide.

37. The method as claimed in claim 23, wherein the first transition metal oxide and the second transition metal oxide are oxidized in their highest degree of oxidation.

38. The method as claimed in claim 23, wherein the provision of the programmable resistance layer is effected by means of reactive sputtering.

39. The method as claimed in claim 38, wherein at least two transition metals are sputtered in a process atmosphere, the process atmosphere comprises oxygen, and the oxygen partial pressure in the process atmosphere is at least saturated such to oxidize the transition metals in their highest degree of oxidation.

40. The method as claimed in claim 39, wherein the process atmosphere comprises an inert gas.

41. The method as claimed in claim 40, wherein the process atmosphere comprises argon.

42-48. (canceled)

49. A memory device, comprising:
a plurality of bottom electrodes;
a top electrode;
a programmable resistance layer situated between the top electrode and the plurality of bottom electrodes, the programmable resistance layer including a first transition metal oxide and a second transition metal oxide;
a plurality of selection transistors corresponding to the plurality of bottom electrodes, the selection transistors each having a gate terminal;
a plurality of word lines, each word line connected to a corresponding gate terminal; and
a bit line connected to the bottom electrodes via the selection transistors.

50. The memory device of claim 49, wherein a first transition metal forms the first transition metal oxide and a second transition metal forms the second transition metal oxide.

51. The memory device of claim 49, wherein a single transition metal forms the first transition metal oxide and the second transition metal oxide.

52. A memory cell, comprising:
a lower electrode;
an upper electrode,
means situated between the lower electrode and the upper electrode for selectively storing data.
